(19) United States
(12) Patent Application Publication
(10) Pub. No.: US 2026/0188630 A1
(43) Pub. Date: Jul. 2, 2026

(54) SUBSTRATE SUPPORT UNIT AND SUBSTRATE PROCESSING APPARATUS INCLUDING THE SAME

(71) Applicant: SEMES CO., LTD., Cheonan-si (KR)

(72) Inventors: AIXIAN ZHANG, Cheonan-si (KR); Dong Beom JANG, Cheonan-si (KR); Ja Myung GU, Cheonan-si (KR)

(73) Assignee: SEMES CO., LTD., Cheonan-si (KR)

(21) Appl. No.: 19/414,542

(22) Filed: Dec. 10, 2025

(30) Foreign Application Priority Data
Dec. 31, 2024 (KR) 10-2024-0202300

(51) Int. Cl. H01J 37/32

(52) U.S. Cl. CPC H01J 37/32697; H01J 37/3211; H01J 37/32128; H01J 37/32715; H01J 2237/334

(57) ABSTRACT

Disclosed are a substrate support unit configured to control the slope of non-sinusoidal bias voltage and a substrate processing apparatus including the same. The substrate support unit is disposed in a chamber body for plasma processing of a substrate and holds the substrate. The substrate support unit includes an electrostatic chuck configured to adsorb the substrate, a bias electrode included in the electrostatic chuck and configured to control plasma characteristics inside the chamber body, and a bias power unit configured to apply a non-sinusoidal wave as bias voltage to the bias electrode. The bias power unit adjusts the slope of a portion of the non-sinusoidal wave and applies the non-sinusoidal wave adjusted in slope as the bias voltage.

### CROSS-REFERENCE TO THE RELATED APPLICATION

The present application claims priority to and the benefit of Korean Patent Application No. 10-2024-0202300, filed on December 31, 2024, in the Korean Intellectual Property Office, the entire disclosure of which is incorporated herein by reference.

### BACKGROUND

### 1. Field

The present disclosure relates to a substrate support unit configured to control the slope of non-sinusoidal bias voltage and to a substrate processing apparatus including the same.

### 2. Description of the Related Art

A substrate processing apparatus is generally used to perform a predetermined processing operation on a substrate such as a semiconductor wafer in order to manufacture a semiconductor device. The predetermined processing operation includes a deposition process of forming a predetermined film on a substrate surface, an etching process of forming a predetermined pattern on the film formed on the substrate, and a cleaning process of physically or chemically cleaning the substrate surface.

The substrate processing apparatus includes a substrate support unit configured to support a substrate. As the substrate support unit, an electrostatic chuck that electrostatically adsorbs and fixes a substrate is commonly used. The electrostatic chuck includes a dielectric plate, which includes a chucking electrode embedded therein and adsorbs and supports the lower surface of a substrate, and a metal base plate, which is disposed below the dielectric plate and functions as a lower electrode for plasma generation or as a substrate cooling unit. The dielectric plate and the base plate are bonded to each other using an adhesive layer.

In the substrate processing apparatus, plasma processing is performed by supplying a process gas to the inside of a chamber and applying radio-frequency (RF) voltage to an upper electrode or a lower electrode so that the process gas is excited to an energy level higher than a reference energy level. In the excited state, plasma is generated, and a substrate adsorbed on the substrate support unit is plasma-processed.

Typically, a bias electrode may be disposed below the chucking electrode in order to control plasma process characteristics such as an etching rate. By applying RF voltage or direct-current (DC) voltage to the bias electrode, energy generated when ions generated in the plasma process reach a substrate surface may be controlled, and ions in the plasma may be aligned in a vertical direction, thereby enabling anisotropic etching. In addition, the bias electrode controls plasma density or enhances uniformity of the substrate surface, thereby controlling characteristics of the plasma process.

Meanwhile, when a sinusoidal wave is applied as RF voltage to the bias electrode, bowing may occur, as shown in FIG. 8, in which a shape of a sidewall of an etched hole excessively expands downward when etching a hole on a substrate surface. In particular, the bowing frequently appears in hole etching having a high aspect ratio, where ions having high energy do not collide in a vertical direction but enter obliquely, thereby additionally etching lower sidewall portions of a trench or a hole.

A more detailed description will be given with reference to the waveform of bias voltage according to the related art shown in FIG. 8. When the bias voltage is applied as a sinusoidal wave, energy of ions is determined by a difference from plasma voltage. As shown in FIG. 8, ion energy exhibits bimodal distribution, in which ions having relatively high energy in region B deeply enter a hole to etch a substrate, while ions having relatively low energy in region A do not collide in a vertical direction but may obliquely etch a sidewall. In particular, in region C, selectivity is low, which is disadvantageous in an etching process having a high aspect ratio.

In order to solve this problem, Korean Patent Laid-Open Publication No. 10-2009-0121982 discloses a technique for adjusting a deflection depth of ions through a multistep etching process in which a plasma chamber pressure or frequency of bias voltage is gradually reduced, or a mass of an inert gas added to an etching gas is gradually increased. However, the bowing phenomenon is not fundamentally solved in a process requiring a high aspect ratio.

### [Related Art Document]

### [Patent Document]

(Patent Document 1) KR 10-2009-0121982 A (Nov. 26, 2009)

### SUMMARY

The present disclosure is directed to providing a substrate support unit and a substrate processing apparatus including the same, which may secure a vertical trench profile by applying a non-sinusoidal wave as bias voltage and controlling a slope of the non-sinusoidal wave.

In addition, the present disclosure is directed to providing a substrate support unit and a substrate processing apparatus including the same, which may secure high selectivity by overcoming a limitation of conventional sinusoidal bias voltage.

A substrate support unit according to an embodiment of the present disclosure, which is disposed in a chamber body for plasma processing of a substrate and holds the substrate, includes an electrostatic chuck configured to adsorb the substrate, a bias electrode included in the electrostatic chuck and configured to control plasma characteristics inside the chamber body, and a bias power unit configured to apply a non-sinusoidal wave as bias voltage to the bias electrode, wherein the bias power unit adjusts the slope of a portion of the non-sinusoidal wave and applies the non-sinusoidal wave adjusted in slope as the bias voltage.

In an embodiment of the present disclosure, the non-sinusoidal wave applied as the bias voltage may be a square wave, and the non-sinusoidal wave may include a first section having a voltage level higher than a reference voltage level, the voltage level being maintained constant for a first time period, and a second section having a voltage level decreasing or increasing with the slope from a level lower than the reference voltage level for a second time period.

In an embodiment of the present disclosure, the first time period or the second time period may be controlled differently during processing of the substrate.

In an embodiment of the present disclosure, the magnitude of a voltage level of the non-sinusoidal wave may be controlled during processing of the substrate.

In an embodiment of the present disclosure, the bias power unit may modulate the non-sinusoidal wave and may apply the modulated non-sinusoidal wave to the bias electrode. The bias power unit may include a first duty cycle having a voltage level of the non-sinusoidal wave set to a first level and a slope having a positive value, a second duty cycle subsequent to the first duty cycle, the second duty cycle having a voltage level of the non-sinusoidal wave set to a second level higher than the first level and a slope having a value close to zero, and a third duty cycle subsequent to the second duty cycle, the third duty cycle having a voltage level of the non-sinusoidal wave set to a third level higher than the second level and a slope having a positive value.

In an embodiment of the present disclosure, the bias power unit may include an idle duty cycle with no bias voltage applied during voltage application.

In accordance with another aspect of the present disclosure, a substrate processing apparatus includes a chamber body for plasma processing of a substrate and a substrate support unit disposed in the chamber body to hold the substrate, wherein the substrate support unit includes an electrostatic chuck configured to adsorb the substrate, a bias electrode included in the electrostatic chuck and configured to control plasma characteristics inside the chamber body, and a bias power unit configured to apply a non-sinusoidal wave as bias voltage to the bias electrode, and the bias power unit adjusts the slope of a portion of the non-sinusoidal wave and applies the non-sinusoidal wave adjusted in slope as the bias voltage.

In an embodiment of the present disclosure, the non-sinusoidal wave applied as the bias voltage may be a square wave, and the non-sinusoidal wave may include a first section having a voltage level higher than a reference voltage level, the voltage level being maintained constant for a first time period, and a second section having a voltage level decreasing or increasing with the slope from a level lower than the reference voltage level for a second time period.

In an embodiment of the present disclosure, the first time period and the second time period may be controlled differently during processing of the substrate.

In an embodiment of the present disclosure, the magnitude of a voltage level of the non-sinusoidal wave may be controlled during processing of the substrate.

In an embodiment of the present disclosure, the bias power unit may modulate the non-sinusoidal wave and may apply the modulated non-sinusoidal wave to the bias electrode. The bias power unit may include a first duty cycle having a voltage level of the non-sinusoidal wave set to a first level and a slope having a positive value, a second duty cycle subsequent to the first duty cycle, the second duty cycle having a voltage level of the non-sinusoidal wave set to a second level higher than the first level and a slope having a value close to zero, and a third duty cycle subsequent to the second duty cycle, the third duty cycle having a voltage level of the non-sinusoidal wave set to a third level higher than the second level and a slope having a positive value.

In an embodiment of the present disclosure, the bias power unit may include an idle duty cycle with no bias voltage applied during voltage application.

In an embodiment of the present disclosure, the substrate processing apparatus may include a first antenna configured to generate plasma in a central region of the chamber body, a second antenna configured to generate plasma in a peripheral region of the chamber body, a first plasma generating unit configured to apply a first radio-frequency (RF) voltage to the first antenna, a second plasma generating unit configured to apply a second RF voltage to the second antenna, and a controller configured to control the bias power unit, the first plasma generating unit, and the second plasma generating unit. The first antenna, the second antenna, the first plasma generating unit, the second plasma generating unit, and the controller may be disposed above the chamber body.

In an embodiment of the present disclosure, the first RF voltage and the second RF voltage may be sinusoidal waves.

In an embodiment of the present disclosure, the controller may control the first plasma generating unit and the second plasma generating unit so that the magnitudes or frequencies of the first RF voltage and the second RF voltage are equal or different.

In an embodiment of the present disclosure, the first RF voltage and the second RF voltage may have different frequencies.

In an embodiment of the present disclosure, the bias power unit may modulate the non-sinusoidal wave and may apply the modulated non-sinusoidal wave to the bias electrode. The bias power unit may include a first duty cycle having a voltage level of the non-sinusoidal wave set to a first level and a first slope and a second duty cycle subsequent to the first duty cycle, the second duty cycle having a voltage level of the non-sinusoidal wave set to a second level different from the first level and a second slope different from the first slope. The chamber body may be maintained in a first process gas state during the first duty cycle, and may be maintained in a second process gas state different from the first process gas state during the second duty cycle.

In an embodiment of the present disclosure, the first process gas state and the second process gas state may be different in composition ratio of process gas.

In an embodiment of the present disclosure, the first process gas state and the second process gas state may have different process pressures of the chamber body.

In accordance with still another aspect of the present disclosure, a substrate processing apparatus includes a chamber body for plasma processing of a substrate, a substrate support unit disposed in the chamber body to hold the substrate, a first antenna disposed above the chamber body and configured to generate plasma in a central region of the chamber body, a second antenna disposed above the chamber body and configured to generate plasma in a peripheral region of the chamber body, a first plasma generating unit configured to apply a first RF voltage to the first antenna, a second plasma generating unit configured to apply a second RF voltage to the second antenna, and a controller configured to control overall operation of the substrate processing apparatus. The substrate support unit includes an electrostatic chuck configured to adsorb the substrate, a bias electrode included in the electrostatic chuck and configured to control plasma characteristics inside the chamber body, and a bias power unit configured to apply a non-sinusoidal wave as bias voltage to the bias electrode. The bias power unit adjusts the slope of a portion of a non-sinusoidal wave having a square waveform and applies the non-sinusoidal wave adjusted in slope as the bias voltage, and the non-sinusoidal wave includes a first section having a voltage level higher than a reference voltage level, the voltage level being maintained constant for a first time period, and a second section having a voltage level decreasing or increasing with the slope from a level lower than the reference voltage level for a second time period. The first time period, the second time period, and the voltage level are controlled differently during processing of the substrate. The bias power unit modulates the non-sinusoidal wave and applies the modulated non-sinusoidal wave to the bias electrode. The bias power unit includes a first duty cycle having a voltage level of the non-sinusoidal wave set to a first level and a first slope, a second duty cycle subsequent to the first duty cycle, the second duty cycle having a voltage level of the non-sinusoidal wave set to a second level different from the first level and a second slope different from the first slope, and a third duty cycle as an idle cycle with no bias voltage applied. The controller controls process gas states inside the chamber body according to the first duty cycle and the second duty cycle.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a view schematically showing the configuration of a substrate processing apparatus according to an embodiment of the present disclosure;

FIG. 2 is a diagram for explaining an effect when a non-sinusoidal wave without a slope is applied as bias voltage in a substrate support unit according to an embodiment of the present disclosure;

FIG. 3 is a diagram for explaining an effect when a non-sinusoidal wave having a positive slope is applied as bias voltage in the substrate support unit according to an embodiment of the present disclosure;

FIG. 4 is a diagram for explaining non-sinusoidal bias voltage in the substrate support unit according to an embodiment of the present disclosure;

FIG. 5 is a diagram for explaining a process of forming a trench having a high aspect ratio using non-sinusoidal bias voltage according to an embodiment of the present disclosure;

FIG. 6 is a diagram for explaining an example of a method of applying non-sinusoidal bias voltage according to an embodiment of the present disclosure;

FIG. 7 is a view schematically showing the configuration of a substrate processing apparatus according to another embodiment of the present disclosure; and

FIG. 8 is a diagram for explaining a problem of a conventional substrate processing apparatus in which a sinusoidal wave is applied as bias voltage.

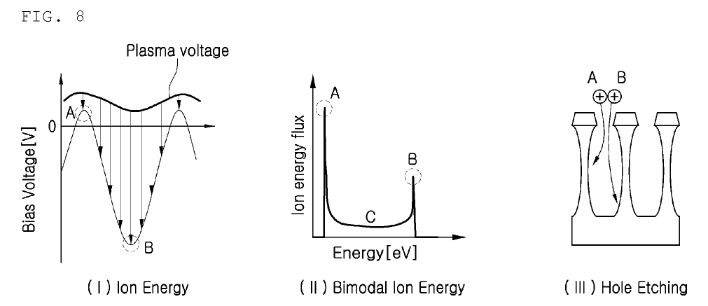

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

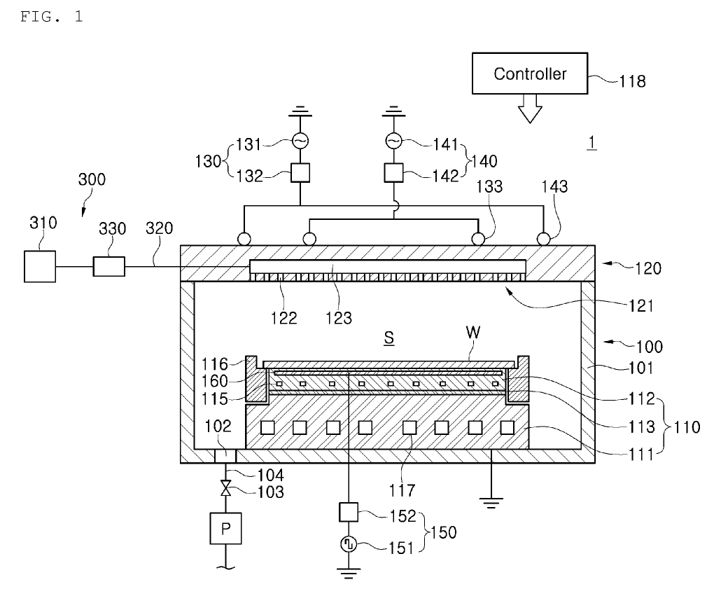

FIG. 1 is a view schematically showing the configuration of a substrate processing apparatus according to an embodiment of the present disclosure.

Referring to FIG. 1, a substrate processing apparatus 1 according to an embodiment of the present disclosure includes a processing chamber 100. The processing chamber 100 provides a processing space S defined in a chamber body 101 in which substrate processing operation is performed. The chamber body 101 may be formed of a metal such as aluminum. The substrate processing operation may be plasma processing operation. The plasma processing operation may be performed under a reduced pressure atmosphere. To this end, an exhaust port 102 may be formed in the processing chamber 100. The exhaust port 102 may be formed in a bottom of the processing chamber. In FIG. 1, the exhaust port 102 is illustrated as a single port, but may be formed in a ring shape around a substrate support unit 110. The exhaust port 102 is connected to an exhaust pump P via an exhaust line 104 and an exhaust valve 103. The pressure in the processing space S in the processing chamber 100 may be adjusted to a predetermined pressure by operating the vacuum pump P and adjusting the exhaust valve 103.

Inside the processing chamber 100, a substrate support unit 110 is provided to support a substrate W. The substrate support unit 110 may include a base plate 111 and a dielectric plate 112 that is supported on the base plate 111 and adsorbs and fixes the substrate W. The base plate 111 and the dielectric plate 112 may be bonded to each other using an adhesive layer 113, and the adhesive layer 113 may be a silicone adhesive or the like.

The dielectric plate 112 may be formed of a dielectric material such as alumina and may be provided therein with a chucking electrode (not shown) to generate electrostatic force. When voltage is applied to the chucking electrode (not shown) by a power supply (not shown), electrostatic force is generated, and the substrate W is adsorbed on and fixed to the dielectric plate 112. The dielectric plate 112 may be provided with a heater 115 to adjust the temperature of the substrate W, but the heater 115 may not be provided depending on the substrate processing operation. The heater 115 may be configured as a plurality of separated zone heaters in order to independently control the temperatures of respective regions of the substrate W.

The base plate 111 may be disposed below the dielectric plate 112 and may be formed of a metal such as aluminum. The base plate 111 may be provided therein with a coolant channel 117 through which a cooling fluid flows, and thus may perform a function of cooling the substrate W. The coolant channel 117 may be provided as a circulation passage through which the cooling fluid circulates.

The substrate support unit 110 may include a ring member 116 surrounding the outer periphery of the dielectric plate 112. The ring member 116 may include a stepped portion formed on an upper side thereof in order to support the outer circumferential surface of the substrate W. The ring member 116 may be formed of a ceramic material and may be a focus ring (F/R).

A showerhead unit 120 may be provided above the processing chamber 100. The showerhead unit 120 may include a shower plate 121 in which a plurality of gas supply holes 122 is formed and a gas distribution chamber 123. A gas supplied from a gas supply unit 300 may flow into the gas distribution chamber 123 through a gas inlet (not shown) and may then be supplied to the processing space S through the gas supply holes 122.

The gas supply unit 300 supplies a gas required for plasma processing to the processing space S. The gas supply unit 300 may include a gas source 310, a gas supply line 320, and a gas flow controller 330. The gas supply line 320 may connect the gas source 310 to a gas inlet (not shown), and the gas flow controller 330 may adjust a flow rate of the gas flowing through the gas supply line 320 or may block the gas supply line 320.

Although one gas source 310, one gas supply line 312, and one gas flow controller 330 are illustrated in FIG. 1, the gas supply unit 300 of the present disclosure may include a plurality of gas sources configured to supply a plurality of gases to the processing space S and a plurality of gas flow controllers configured to independently control supply of the respective gases. The plurality of gases may be etching gases used to etch a processing film formed on the substrate W. The etching gases may include, for example, fluorine (F)-based gases. In addition, the plurality of gases may further include gases containing oxygen (O), inert gases, or other gases.

A first antenna 133 and a second antenna 143 may be provided as upper electrodes for plasma generation above the processing chamber 100. The first antenna 133 and the second antenna 143 may be provided in various forms. For example, the first antenna 133 may be an inner coil in a concentric or spiral form, and the second antenna 143 may be an outer coil in a concentric or spiral form. The first antenna 133 and the second antenna 143 may generate inductively coupled plasma that is inductively coupled to the processing space S in the processing chamber 100. The first antenna 133 and the second antenna 143 shown in FIG. 1 are merely illustrative, and the present disclosure is not limited as to the number or arrangement of coils of the first antenna 133 and the second antenna 143.

A first plasma generating unit 140 configured to apply voltage for plasma generation to the first antenna 133 and a second plasma generating unit 130 configured to apply voltage for plasma generation to the second antenna 143 may be included. The first plasma generating unit 140 may include a first radio-frequency (RF) power supply 141 configured to apply RF voltage to generate plasma in the processing space S and a first matcher 142 configured to perform impedance matching. The first RF power supply 141 may apply RF voltage in a range of several hundred kHz to several hundred MHz. The second plasma generating unit 130 may include a second RF power supply 131 configured to apply RF voltage to generate plasma in the processing space S and a second matcher 132 configured to perform impedance matching. The second RF power supply 131 may apply RF voltage in a range of several hundred kHz to several hundred MHz. In this case, the substrate support unit 110 functioning as a lower electrode may be grounded.

Although the plasma source is illustrated in FIG. 1 as being an inductively coupled plasma (ICP) source, this should be understood as being merely illustrative. The plasma source of the present disclosure is not limited to the ICP source, and various methods capable of generating plasma, such as capacitively coupled plasma (CCP), remote plasma, and microwave plasma, in the processing space S may also be applied thereto.

A bias electrode 160 may be disposed below the chucking electrode (not shown) in order to control plasma characteristics in the processing space S, such as an etching rate. By applying sinusoidal or non-sinusoidal voltage to the bias electrode 160, energy generated when ions generated in the plasma process reach a substrate surface may be controlled, and ions in the plasma may be aligned in a vertical direction, thereby enabling anisotropic etching.

A bias power unit 150 configured to apply bias voltage for controlling ion behavior to the bias electrode 160 may be included. In an embodiment, the bias power unit 150 may include a bias power supply 151. For example, the bias power supply 151 may include an RF power source. The bias power unit 150 may apply a non-sinusoidal wave with an adjusted slope from a bias power supply 151 to the bias electrode 160 in response to a bias voltage control signal from a controller 118. A non-sinusoidal wave from the bias power supply 151 may have different slopes in portions of the waveform, and voltage level and frequency may also be variable. The bias power unit 150 may further include a modulator 152 configured to modulate the waveform generated from the bias power supply 151. Modulation of the slope of the non-sinusoidal wave and voltage level will be described in detail later.

### (First Embodiment)

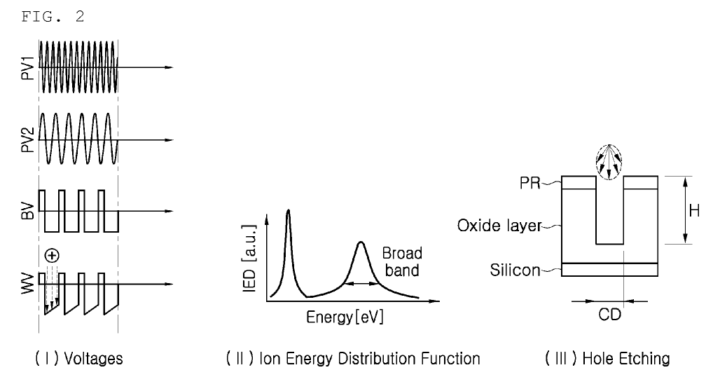

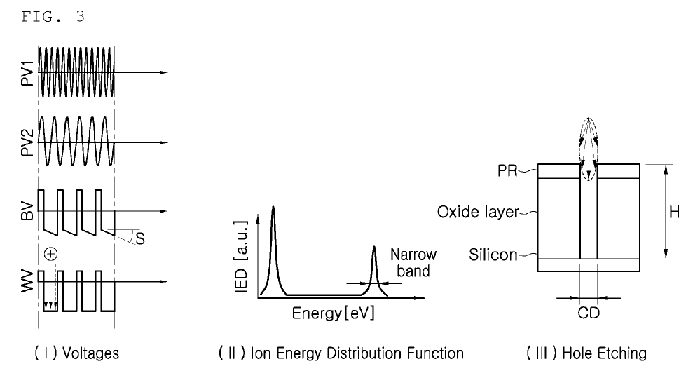

Modulation of the slope of a non-sinusoidal wave applied as bias voltage and an effect thereof according to an embodiment of the present disclosure will be described in detail with reference to FIGS. 2 and 3. FIG. 2 is a diagram for explaining an effect when a non-sinusoidal wave without a slope is applied as bias voltage in the substrate support unit according to an embodiment of the present disclosure, and FIG. 3 is a diagram for explaining an effect obtained by a non-sinusoidal wave having a positive slope as bias voltage.

The substrate support unit according to an embodiment of the present disclosure is characterized in that non-sinusoidal bias voltage is applied to the bias electrode, and a portion of the non-sinusoidal wave is modulated to have a slope.

As shown in FIG. 2, a first plasma voltage PV1 applied to the first antenna 133 by the first plasma generating unit 140 and a second plasma voltage PV2 applied to the second antenna 143 by the second plasma generating unit 130 may be sinusoidal waves. The magnitudes of the voltages may be equal or different, and the frequencies may also be equal or different. When bias voltage BV applied to the bias electrode 160 by the bias power unit 150 is given as a square wave as shown in FIG. 2, substrate voltage WV actually applied to the substrate W due to charging at the dielectric plate 112 of the substrate support unit 110 and the substrate W is modulated such that a portion of the square wave has a positive slope. Accordingly, distribution of ion energy applied to plasma ions due to a difference between the substrate voltage WV and each of the first plasma voltage PV1 and the second plasma voltage PV2 has a relatively broad band. Due to the broad-band ion energy distribution, the plasma ions become less collimated, the incident angle distribution into a trench is broadened, and as a result, the critical dimension (CD) of the trench increases whereas the depth H of the trench decreases.

Meanwhile, as shown in FIG. 3, when the first plasma voltage PV1 applied to the first antenna 133 by the first plasma generating unit 140 and the second plasma voltage PV2 applied to the second antenna 143 by the second plasma generating unit 130 are sinusoidal waves and when the bias voltage BV applied to the bias electrode 160 by the bias power unit 150 is a square wave and is modulated such that the slope S of a portion of the square wave has a positive value, distribution of ion energy applied to plasma ions due to a difference between the substrate voltage WV and each of the first plasma voltage PV1 and the second plasma voltage PV2 has a relatively narrow band. Accordingly, due to the narrow-band ion energy distribution, plasma ions become more collimated, the incident angle distribution into a trench is narrowed, and plasma ions penetrate deeper into the trench, resulting in decrease in the critical dimension (CD) of the trench and increase in the depth H of the trench.

According to an embodiment of the present disclosure, by modulating the slope of a portion of the non-sinusoidal wave applied to the bias electrode 160, the energy distribution of plasma ions may be changed, thereby altering ion behavior and enabling implementation of various trench profiles to be etched.

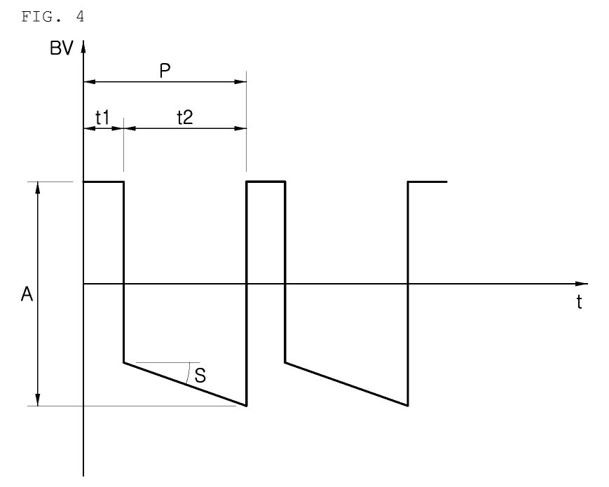

Next, an example of modulated bias voltage according to an embodiment of the present disclosure will be described in detail with reference to FIG. 4. The bias voltage of the present disclosure is a non-sinusoidal wave having a square waveform, and is modulated such that a portion of the square waveform has a slope. The sign of the slope is described based on an absolute value of the bias voltage.

First, one period P of the non-sinusoidal wave is divided into two sections. A first section may have a fixed voltage level (e.g., about A/2) higher than a reference voltage level (e.g., about 0 V) and may be maintained for a time period of approximately t1. A second section may be a kind of ramp section in which the bias voltage BV decreases with a constant slope S from a voltage level (e.g., about 80% of A/2) lower than the reference voltage level. In the present disclosure, as shown in FIG. 4, when voltage decreases in the second section, the slope S is considered to have a positive value. The second section may be maintained for a time period of approximately t2.

In an embodiment of the present disclosure, the magnitude A of the bias voltage BV, the slope S of the second section, and the durations t1 and t2 of the two sections may be modulated in response to a bias voltage control signal of the controller 118.

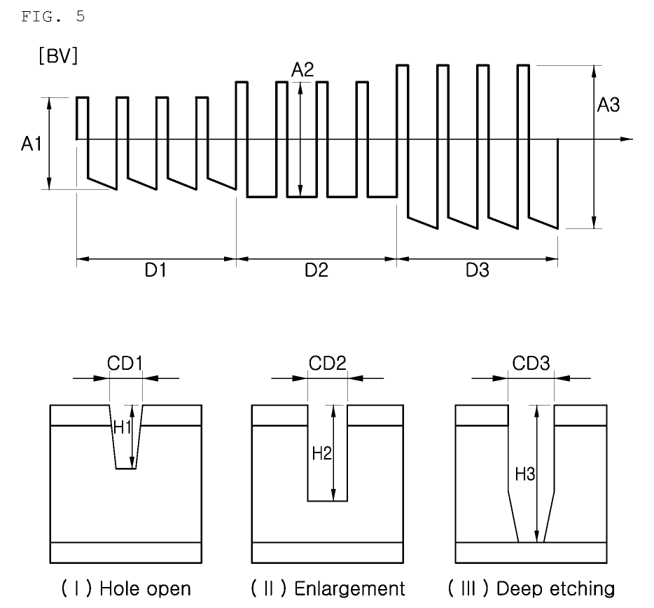

Next, an exemplary process of forming a hole having a high aspect ratio using non-sinusoidal bias voltage according to an embodiment of the present disclosure will be described in detail with reference to FIG. 5. In the present disclosure, the bias power unit 150 is configured to modulate non-sinusoidal bias voltage and to apply the modulated non-sinusoidal bias voltage to the bias electrode 160. The modulation may include modulating the slope S of the non-sinusoidal wave, the magnitude A of the bias voltage BV, or the durations t1 and t2 (see FIG. 4) of the divided sections, or may include varying duty cycle for maintaining the modulated waveform.

For example, as shown in FIG. 5, in a first duty cycle D1, the slope S of the non-sinusoidal wave may have a positive value, and the voltage magnitude may be A1. In a subsequent second duty cycle D2, the slope S of the non-sinusoidal wave may be approximately zero, and the voltage magnitude may be A2. In a subsequent third duty cycle D3, the slope S of the non-sinusoidal wave may have a positive value, and the voltage magnitude may be A3. The voltage magnitude A2 in the second duty cycle D2 may be greater than the voltage magnitude A1 in the first duty cycle D1, and the voltage magnitude A3 in the third duty cycle D3 may be greater than the voltage magnitude A2 in the second duty cycle D2.

In the first duty cycle D1, energy distribution of the plasma ions has a relatively narrow band, resulting in narrow ion incident angle distribution, high collimation, and relatively low energy level. Accordingly, a hole having a relatively small critical dimension CD1 and a relatively small depth H1 may be formed. This may be referred to as “Hole Open.” Subsequently, in the second duty cycle D2, energy distribution of the plasma ions has a relatively broad band, resulting in broad ion incident angle distribution, slightly reduced collimation, and relatively high energy level. Accordingly, the critical dimension of the trench may increase to CD2, and the depth of the trench may increase to H2. This may be referred to as “Enlargement.” Subsequently, in the third duty cycle D3, energy distribution of the plasma ions has a narrow band, resulting in narrow ion incident angle distribution, high collimation, and greatly increased energy level. Accordingly, the critical dimension of the trench may slightly increase to CD3, and the depth of the trench may increase to H3. This may be referred to as “Deep Etching.” According to the first duty cycle D1 to the third duty cycle D3 shown by way of example, a hole having relatively small tapering, excellent verticality, and a high aspect ratio may be formed. As described above, according to an embodiment of the present disclosure, an ideal etching profile may be constructed by modulating the slope and magnitude of non-sinusoidal bias voltage.

### (Second Embodiment)

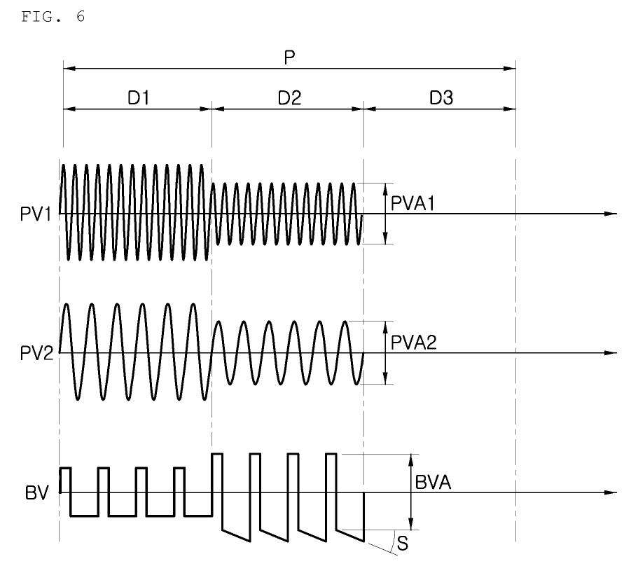

Next, with reference to FIG. 6, a substrate support unit according to a second embodiment of the present disclosure will be described in detail in comparison with the first embodiment. The substrate support unit according to the second embodiment of the present disclosure may not only modulate the bias voltage, that is, vary the slope S or magnitude BVA of the bias voltage, but may also vary the magnitude PVA1 of the first plasma voltage PV1 applied to the first antenna 133 by the first plasma generating unit 140 and the magnitude PVA2 of the second plasma voltage PV2 applied to the second antenna 143 by the second plasma generating unit 130. Furthermore, the substrate support unit may vary the frequency of the first plasma voltage PV1 and the frequency of the second plasma voltage PV2.

In the substrate support unit according to the second embodiment of the present disclosure, as shown in FIG. 6, one period P may include a plurality of duty cycles D1 and D2 in which the bias voltage BV is modulated differently, the magnitude PVA1 or frequency of the first plasma voltage PV1 is varied differently, or the magnitude PVA2 or frequency of the second plasma voltage PV2 is varied differently.

In addition, in the substrate support unit according to the second embodiment of the present disclosure, one period P may further include an idle duty cycle D3 in which the first plasma voltage PV1, the second plasma voltage PV2, and the bias voltage BV are not applied. Due to the idle duty cycle D3, ion energy may be reduced, thereby preventing damage to a substrate that is formed of a sensitive material or has a thin structure. Furthermore, the plasma state may be stably maintained, and excessive etching may be prevented through selectivity control.

In the substrate support unit according to the second embodiment of the present disclosure, the controller 118 may generate hole profiles in various combinations through control of the first plasma generating unit 140 configured to apply plasma voltage to the first antenna 133, the second plasma generating unit 130 configured to apply plasma voltage to the second antenna 143, and the bias power unit 150.

As a first example, in the first duty cycle D1 within one period P, the slope S of the bias voltage BV may have a positive value so that the slope of the substrate voltage WV (see FIG. 2 or FIG. 3) has a value of zero or close to zero, and in the second duty cycle D2, the slope S of the bias voltage BV may have a value close to zero so that the slope of the substrate voltage WV has a negative value.

In addition, as a second example, the first duty cycle D1 and the second duty cycle D2 in the first example may be repeated, an order thereof may be changed, or a maintenance ratio between the first duty cycle D1 and the second duty cycle D2 may be adjusted.

In addition, as a third example, in addition to the first example, a third duty cycle D3, which is an idle duty cycle in which the bias voltage BV is not applied, may further be included in one period P.

In addition, as a fourth example, in the first example and the third example, a ratio of the magnitude PVA1 of the first plasma voltage PV1 to the magnitude PVA2 of the second plasma voltage PV2 and the frequencies of the voltages in the first duty cycle D1 and the second duty cycle D2 may be changed.

In addition, as a fifth example, in the first example or the third example, the frequency of the first plasma voltage PV1 may be relatively high, and the frequency of the second plasma voltage PV2 may be relatively low. Alternatively, the frequency of the first plasma voltage PV1 may be relatively low, and the frequency of the second plasma voltage PV2 may be relatively high.

In addition, as a sixth example, process gases supplied to the gas supply holes 122 in the first duty cycle D1 and the second duty cycle D2 may be different from each other. That is, in the first duty cycle D1, the bias voltage BV may be modulated to be suitable for a first process gas, and in the second duty cycle D2, the bias voltage BV may be modulated to be suitable for a second process gas.

In addition, as a seventh example, in the sixth example, the magnitudes and frequencies of the first plasma voltage PV1 and the second plasma voltage PV2 may be changed. Furthermore, a composition ratio of the process gas or process pressure in the chamber body 101 may be changed.

In addition, as an eighth example, in the seventh example, one of the frequency of the first plasma voltage PV1 and the frequency of the second plasma voltage PV2 may be relatively high, and the other frequency may be relatively low. Furthermore, the two frequencies may not be significantly different from each other.

In addition, as a ninth example, in the first example and the sixth example, an incident direction of plasma ions incident on the substrate may be controlled by adjusting the slope of the substrate voltage WV, thereby increasing the verticality of a hole.

In addition, as a tenth example, in the first example and the sixth example, when one of the frequency of the first plasma voltage PV1 and the frequency of the second plasma voltage PV2 is relatively high and the other frequency is relatively low, a ratio of the magnitude PVA1 of the first plasma voltage PV1 to the magnitude PVA2 of the second plasma voltage PV2 may be controlled to control a chemical composition ratio of the plasma process gas.

### (Third Embodiment)

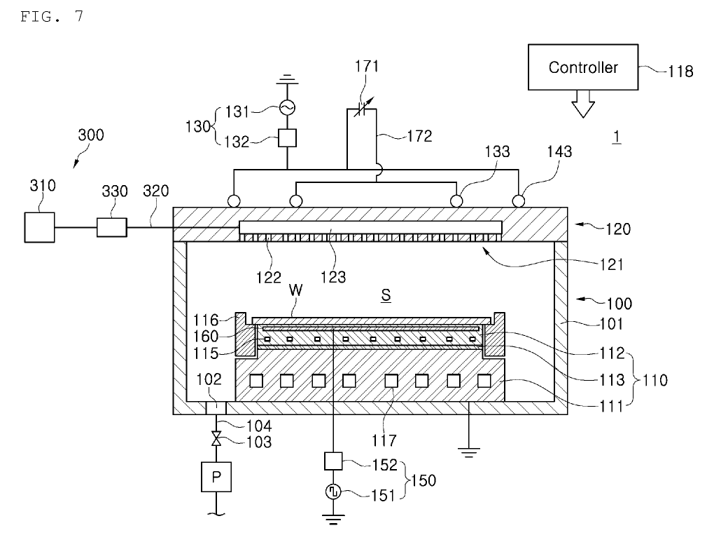

Next, a substrate processing apparatus according to a third embodiment of the present disclosure will be described in detail with reference to FIG. 7. The configuration identical or similar to that of the first embodiment of the present disclosure will not be redundantly described, but the technical features are not limited thereto.

A plasma generating unit 130 of the third embodiment of the present disclosure is characterized by being merged into a single unit. Similar to the first embodiment, the plasma generating unit 130 includes an RF power supply 131 configured to apply a sinusoidal wave and a matcher 132. In addition, the plasma generating unit 130 may further include a variable condenser 171 configured to adjust power applied to the first antenna 133 and the second antenna 143. In addition, the plasma generating unit 130 of the present disclosure may further include a passive element in order to maintain stable operation and performance.

According to the third embodiment of the present disclosure, although a plurality of different antennas 133 and 143 is provided above the chamber body 101 and plasma voltage is applied by a single plasma generating unit 130, a uniform plasma region may be generated in the processing space S.

As is apparent from the above description, according to an embodiment of the present disclosure, a trench profile having high verticality may be implemented by modulating the slope of non-sinusoidal bias voltage applied to a bias electrode.

According to an embodiment of the present disclosure, because non-sinusoidal bias voltage modulated in slope, magnitude, or frequency is applied to the bias electrode, a higher level of selectivity may be secured than when conventional sinusoidal voltage is applied.

According to an embodiment of the present disclosure, behavior of plasma ions may be controlled by modulating non-sinusoidal bias voltage, thereby achieving anisotropic etching with a high aspect ratio.

Although the exemplary embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the accompanying claims, and all technical ideas within the scope of equivalents to the claims should be construed as falling within the scope of the disclosure.

What is claimed is:

1. A substrate support unit disposed in a chamber body for plasma processing of a substrate and holding of the substrate, the substrate support unit comprising:
an electrostatic chuck configured to adsorb the substrate;
a bias electrode included in the electrostatic chuck, the bias electrode being configured to control plasma characteristics inside the chamber body; and
a bias power unit configured to:
generate a non-sinusoidal wave;
adjust a slope of a portion of the non-sinusoidal wave; and
apply the non-sinusoidal wave, with the adjusted slope, to the bias electrode as a bias voltage.

2. The substrate support unit as claimed in claim 1, wherein the non-sinusoidal wave applied as the bias voltage is a square wave, and
wherein the non-sinusoidal wave comprises:
a first section having a voltage level higher than a reference voltage level, the voltage level being maintained constant for a first time period; and
a second section having a voltage level decreasing or increasing with the slope from a level lower than the reference voltage level for a second time period.

3. The substrate support unit as claimed in claim 2, wherein the first time period or the second time period is controlled differently during processing of the substrate.

4. The substrate support unit as claimed in claim 3, wherein a magnitude of a voltage level of the non-sinusoidal wave is controlled during processing of the substrate.

5. The substrate support unit as claimed in claim 4, wherein the bias power unit modulates the non-sinusoidal wave and applies the modulated non-sinusoidal wave to the bias electrode, the bias power unit comprising:
a first duty cycle having a voltage level of the non-sinusoidal wave set to a first level and a slope having a positive value;
a second duty cycle subsequent to the first duty cycle, the second duty cycle having a voltage level of the non-sinusoidal wave set to a second level higher than the first level and a slope having a value close to zero; and
a third duty cycle subsequent to the second duty cycle, the third duty cycle having a voltage level of the non-sinusoidal wave set to a third level higher than the second level and a slope having a positive value.

6. The substrate support unit as claimed in claim 5, wherein the bias power unit comprises an idle duty cycle with no bias voltage applied during voltage application.

7. A substrate processing apparatus comprising:
a chamber body for plasma processing of a substrate; and
a substrate support unit disposed in the chamber body to hold the substrate,
wherein the substrate support unit comprises:
an electrostatic chuck configured to adsorb the substrate;
a bias electrode included in the electrostatic chuck, the bias electrode being configured to control plasma characteristics inside the chamber body; and
a bias power unit configured to:
generate a non-sinusoidal wave;
adjust a slope of a portion of the non-sinusoidal wave; and
apply the non-sinusoidal wave, with the adjusted slope, to the bias electrode as a bias voltage.

8. The substrate processing apparatus as claimed in claim 7, wherein the non-sinusoidal wave applied as the bias voltage is a square wave, and
wherein the non-sinusoidal wave comprises:
a first section having a voltage level higher than a reference voltage level, the voltage level being maintained constant for a first time period; and
a second section having a voltage level decreasing or increasing with the slope from a level lower than the reference voltage level for a second time period.

9. The substrate processing apparatus as claimed in claim 8, wherein the first time period and the second time period are controlled differently during processing of the substrate.

10. The substrate processing apparatus as claimed in claim 9, wherein a magnitude of a voltage level of the non-sinusoidal wave is controlled during processing of the substrate.

11. The substrate processing apparatus as claimed in claim 10, wherein the bias power unit modulates the non-sinusoidal wave and applies the modulated non-sinusoidal wave to the bias electrode, the bias power unit comprising:
a first duty cycle having a voltage level of the non-sinusoidal wave set to a first level and a slope having a positive value;
a second duty cycle subsequent to the first duty cycle, the second duty cycle having a voltage level of the non-sinusoidal wave set to a second level higher than the first level and a slope having a value close to zero; and
a third duty cycle subsequent to the second duty cycle, the third duty cycle having a voltage level of the non-sinusoidal wave set to a third level higher than the second level and a slope having a positive value.

12. The substrate processing apparatus as claimed in claim 7, wherein the bias power unit comprises an idle duty cycle with no bias voltage applied during voltage application.

13. The substrate processing apparatus as claimed in claim 7, comprising:
a first antenna configured to generate plasma in a central region of the chamber body;
a second antenna configured to generate plasma in a peripheral region of the chamber body;
a first plasma generating unit configured to apply a first radio-frequency (RF) voltage to the first antenna;
a second plasma generating unit configured to apply a second RF voltage to the second antenna; and
a controller configured to control the bias power unit, the first plasma generating unit, and the second plasma generating unit,
wherein the first antenna, the second antenna, the first plasma generating unit, the second plasma generating unit, and the controller are disposed above the chamber body.

14. The substrate processing apparatus as claimed in claim 13, wherein the first RF voltage and the second RF voltage are sinusoidal waves.

15. The substrate processing apparatus as claimed in claim 14, wherein the controller controls the first plasma generating unit and the second plasma generating unit so that magnitudes or frequencies of the first RF voltage and the second RF voltage are equal or different.

16. The substrate processing apparatus as claimed in claim 14, wherein the first RF voltage and the second RF voltage have different frequencies.

17. The substrate processing apparatus as claimed in claim 10, wherein the bias power unit modulates the non-sinusoidal wave and applies the modulated non-sinusoidal wave to the bias electrode, the bias power unit comprising:
a first duty cycle having a voltage level of the non-sinusoidal wave set to a first level and a first slope; and
a second duty cycle subsequent to the first duty cycle, the second duty cycle having a voltage level of the non-sinusoidal wave set to a second level different from the first level and a second slope different from the first slope, and
wherein the chamber body is maintained in a first process gas state during the first duty cycle, and is maintained in a second process gas state different from the first process gas state during the second duty cycle.

18. The substrate processing apparatus as claimed in claim 17, wherein the first process gas state and the second process gas state are different in composition ratio of process gas.

19. The substrate processing apparatus as claimed in claim 17, wherein the first process gas state and the second process gas state have different process pressures of the chamber body.

20. A substrate processing apparatus comprising:
a chamber body for plasma processing of a substrate;
a substrate support unit disposed in the chamber body to hold the substrate;
a first antenna disposed above the chamber body, the first antenna being configured to generate plasma in a central region of the chamber body;
a second antenna disposed above the chamber body, the second antenna being configured to generate plasma in a peripheral region of the chamber body;
a first plasma generating unit configured to apply a first RF voltage to the first antenna;
a second plasma generating unit configured to apply a second RF voltage to the second antenna; and
a controller configured to control overall operation of the substrate processing apparatus,
wherein the substrate support unit comprises:
an electrostatic chuck configured to adsorb the substrate;
a bias electrode included in the electrostatic chuck, the bias electrode being configured to control plasma characteristics inside the chamber body; and
a bias power unit configured to apply a non-sinusoidal wave as bias voltage to the bias electrode,
wherein the bias power unit adjusts a slope of a portion of a non-sinusoidal wave having a square waveform and applies the non-sinusoidal wave adjusted in slope as the bias voltage,
wherein the non-sinusoidal wave comprises:
a first section having a voltage level higher than a reference voltage level, the voltage level being maintained constant for a first time period; and
a second section having a voltage level decreasing or increasing with the slope from a level lower than the reference voltage level for a second time period,
wherein the first time period, the second time period, and the voltage level are controlled differently during processing of the substrate,
wherein the bias power unit modulates the non-sinusoidal wave and applies the modulated non-sinusoidal wave to the bias electrode, the modulated non-sinusoidal wave of the bias power unit comprising:
a first duty cycle having a voltage level of the non-sinusoidal wave set to a first level and a first slope;
a second duty cycle subsequent to the first duty cycle, the second duty cycle having a voltage level of the non-sinusoidal wave set to a second level different from the first level and a second slope different from the first slope; and
a third duty cycle as an idle cycle with no bias voltage applied, and
wherein the controller controls process gas states inside the chamber body according to the first duty cycle and the second duty cycle.
